(19) United States
(12) Patent Application Publication
(10) Pub. No.: US 2011/0095875 A1
(43) Pub. Date: Apr. 28, 2011

(54) ADJUSTMENT OF MEDIA DELIVERY PARAMETERS BASED ON AUTOMATICALLY-LEARNED USER PREFERENCES

(75) Inventors: Jes Thyssen, Laguna Niguel, CA (US); Wilfrid LeBlanc, Vancouver (CA)

(73) Assignee: BROADCOM CORPORATION, Irvine, CA (US)

(21) Appl. No.: 12/751,381

(22) Filed: Mar. 31, 2010

Related U.S. Application Data
(60) Provisional application No. 61/254,430, filed on Oct. 23, 2009.

(51) Int. Cl. H04B 3/36; H03G 3/20; G09G 5/10; G09G 5/00

(52) U.S. Cl. 340/407.1; 381/57; 345/690; 345/207

(57) ABSTRACT

Systems and methods are described that automatically adjust a value of a parameter relating to the delivery of media content, such as audio content or image content, based on both environmental conditions and on automatically-learned user preference data. For example, a first embodiment adjusts a volume setting used to control the delivery of an audio signal based both on environmental noise conditions and upon automatically-learned user preference information, wherein the user preference information is derived by monitoring user-implemented adjustments to the volume setting after application of an automatic adjustment thereto. As another example, a second embodiment adjusts a brightness setting used to control the brightness of a display used for rendering images based both on an ambient light level and upon automatically-learned user preference information, wherein the user preference information is derived by monitoring user-implemented adjustments to the brightness setting after application of an automatic adjustment thereto.

### CROSS-REFERENCE TO RELATED APPLICATIONS

This application claims priority to U.S. Provisional Patent Application No. 61/254,430, filed Oct. 23, 2009, the entirety of which is incorporated by reference herein.

### BACKGROUND OF THE INVENTION

1. Field of the Invention

The invention generally relates to systems and devices that are capable of automatically adjusting parameters relating to the delivery of media content based on environmental conditions.

2. Background

Systems and devices exist that automatically monitor a level of ambient background noise and adjust the volume of an output audio signal based on current background noise conditions. For example, such systems and devices may increase the volume of an output audio signal in response to a detected increase in ambient background noise or reduce the volume of the output audio signal in response to a detected reduction in ambient background noise. This feature, which is sometimes referred to as “automatic volume control” or “automatic volume boost,” is intended to eliminate the need for constant manual volume adjustments by a user in variable noise situations such as driving. The feature has been implemented, for example, in certain car stereo systems and Bluetooth® headsets.

Different users may have different preferences in terms of the amount of volume adjustment that should be applied when this feature is active. For example, a user that is hard of hearing may prefer that the automatic volume control feature apply a greater increase in volume at a particular level of ambient background noise than that desired by a user that is not hard of hearing. As another example, a user that is uncomfortable with loud audio signals may prefer that the automatic volume control feature apply a lesser increase in volume at a particular level of ambient background noise than that desired by a user that is comfortable with loud audio signals or that has a poor ear seal in the case of an audio headset or earphones. If the automatic volume control feature does not apply the desired level of volume adjustment, then the user will still be required to make manual volume adjustments, which essentially defeats the purpose of the feature.

To address this issue, certain car stereo systems allow a user to select from a number of predefined automatic volume control settings, wherein each setting provides a different degree of volume adjustment in response to the level of ambient background noise. However, such systems are limited in that they require the user to manually select and activate each setting until a satisfactory degree of volume adjustment is achieved for a particular operating environment. Furthermore, such systems are limited in that it is possible that none of the predefined settings will provide a user with a satisfactory listening experience. Many other devices that provide automatic volume control provide only a “one size fits all” solution—i.e., the degree of volume adjustment applied in response to the level of ambient background noise is determined in a manner that is entirely independent of user preferences.

Systems and devices also exist that automatically sense an ambient light level and adjust the brightness of a display used to render images based on the current ambient light level. For example, such devices may increase the brightness of a display in response to a detected increase in ambient light and reduce the brightness of the display in response to a detected reduction in ambient light. This feature, which is sometimes referred to as “automatic brightness adjustment” or “auto-brightness,” is intended to eliminate the need for brightness adjustments by a user when lighting conditions are changing, such as when the user is moving from indoors to outdoors. The feature has been implemented, for example, in certain portable electronic devices that include displays such as cellular telephones and portable media players.

Different users may have different preferences in terms of the amount of brightness adjustment that should be applied when this feature is active. However, devices that implement this feature typically provide only a “one size fits all” solution—i.e., the degree of brightness adjustment applied in response to the level of ambient light is determined in a manner that is entirely independent of user preferences. Consequently, if the automatic brightness control feature does not provide the desired amount of brightness adjustment, then the user will be required to make manual brightness adjustments (assuming that the device even allows this), which essentially defeats the purpose of the feature.

### BRIEF SUMMARY OF THE INVENTION

Systems and methods are described herein that automatically adjust a value of a parameter relating to the delivery of media content, such as audio or image content, based on both environmental conditions and on automatically-learned user preference data. For example, a first embodiment described herein adjusts a volume setting used to control the delivery of an audio signal based both on environmental noise conditions and upon automatically-learned user preference information, wherein the user preference information is derived by monitoring user-implemented adjustments to the volume setting after application of an automatic adjustment thereto. As another example, a second embodiment described herein adjusts a brightness setting used to control the brightness of a display used for rendering images based both on an ambient light level and upon automatically-learned user preference information, wherein the user preference information is derived by monitoring user-implemented adjustments to the brightness setting after application of an automatic adjustment thereto.

Because these embodiments perform automatic parameter adjustments in a manner that takes into account automatically-learned user preference information, such embodiments will automatically adapt the degree of automated adjustment to the preferences of a particular user. Consequently, these embodiments represent an advance over prior art “one size fits all” automatic volume and brightness control schemes that do not consider user preferences at all in performing automatic parameter adjustments. As discussed in the Background Section above, such prior art control schemes may require the user to make ongoing manual adjustments to the relevant parameter if the automatic adjustments do not provide a satisfactory listening or viewing experience. In contrast, by incorporating automatically-learned user preference information into the automatic parameter adjustment function, embodiments described herein can significantly reduce the number of manual adjustments that a user must make over time to achieve a satisfactory and personalized listening or viewing experience.

Embodiments described herein also represent an advance over prior art car stereo systems that provide users with a number of predefined automatic volume control settings in that the embodiments described herein do not require a user to actively select a particular automatic parameter control scheme and then determine whether such a selected scheme provides a satisfactory listening or viewing experience. Rather, embodiments described herein automatically learn a user's preferences in regard to automatic parameter control by monitoring manual user changes to the relevant parameter after an automatic adjustment has been applied thereto. These user preferences are then automatically and seamlessly incorporated into the automatic parameter control function to select a desired parameter setting for the user in a variety of environmental conditions.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present invention and, together with the description, further serve to explain the principles of the invention and to enable a person skilled in the relevant art(s) to make and use the invention.

FIG. 1 is a block diagram of a system that performs automatic parameter adjustment based on automatically-learned user preferences in accordance with an embodiment of the present invention.

FIG. 2 depicts a flowchart of a method for performing automatic parameter adjustment based on automatically-learned user preferences in accordance with an embodiment of the present invention.

FIG. 3 is a block diagram of a system that performs automatic volume adjustment based on automatically-learned user preferences in accordance with an embodiment of the present invention

FIG. 4 is a block diagram of an example automatic volume adjustment module in accordance with an embodiment of the present invention.

FIG. 5 illustrates an example look-up table for storing target signal-to-noise ratios in accordance with an embodiment of the present invention.

FIG. 6 depicts a flowchart of a method for performing automatic volume adjustment based on automatically-learned user preferences in accordance with an embodiment of the present invention.

FIG. 7 is a block diagram of a system that performs automatic brightness adjustment based on automatically-learned user preferences in accordance with an embodiment of the present invention.

FIG. 8 depicts a flowchart of a method for performing automatic brightness adjustment based on automatically-learned user preferences in accordance with an embodiment of the present invention.

FIG. 9 is a block diagram of an exemplary processor-based system that may be used to implement aspects of the present invention.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### DETAILED DESCRIPTION OF THE INVENTION

### A. Introduction

The following detailed description of the present invention refers to the accompanying drawings that illustrate exemplary embodiments consistent with this invention. Other embodiments are possible, and modifications may be made to the embodiments within the spirit and scope of the present invention. Therefore, the following detailed description is not meant to limit the invention. Rather, the scope of the invention is defined by the appended claims.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to implement such feature, structure, or characteristic in connection with other embodiments whether or not explicitly described.

### B. General System and Method for Adjusting Media Delivery Parameters Based on Automatically-Learned User Preferences

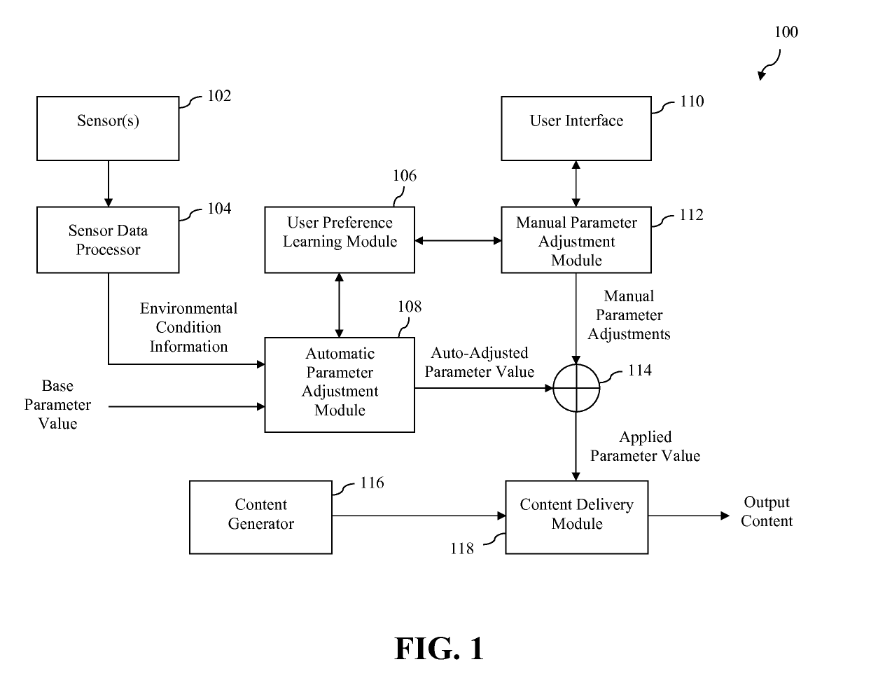

FIG. 1 is a block diagram of an example system 100 that performs automatic media delivery parameter adjustment based on automatically-learned user preferences in accordance with an embodiment of the present invention. As will be appreciated by persons skilled in the relevant art(s) based on the teachings provided herein, system 100 may be implemented as part of any system or device that delivers media content, such as audio and/or image content, to a user. As shown in FIG. 1, system 100 includes one or more sensors 102, a sensor data processor 104, a user preference learning module 106, an automatic parameter adjustment module 108, a user interface 110, a manual parameter adjustment module 112, a combiner 114, a content generator 116 and a content delivery module 118. Each of these elements will now be described.

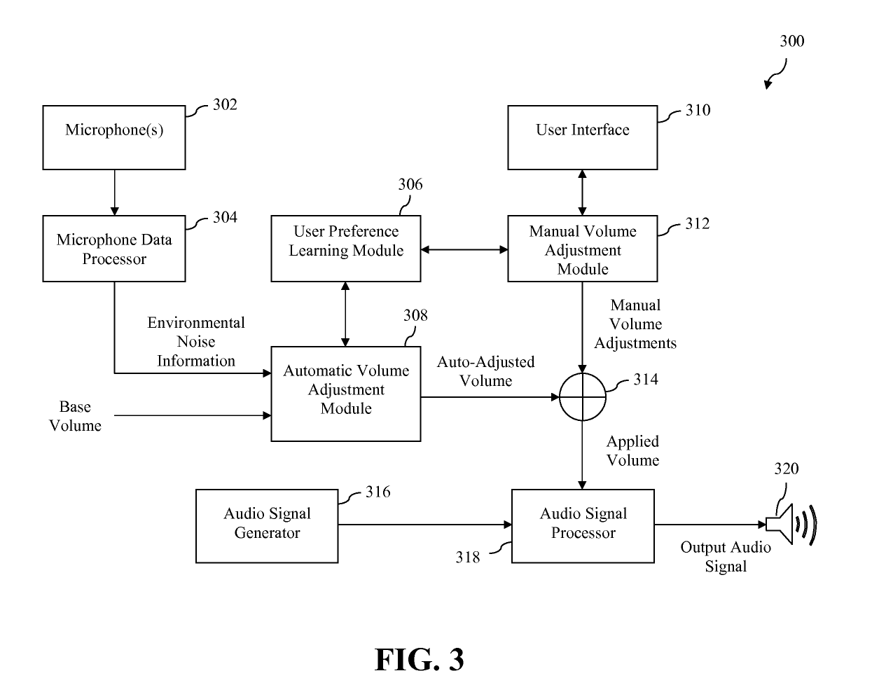

Content generator 116 comprises one or more components that operate to produce media content for presentation to a user via content delivery module 118. The media content may comprise, for example, an audio signal, an image, or some other type of media content. Depending upon the implementation, content generator 116 may obtain the media content from a system or device, such as a storage system or device, that is directly connected to or integrated with system 100 or from a system or device that is connected to system 100 via a network, such as a local or wide area data network or a telecommunications network. Depending upon the implementation, producing the media content may comprise performing operations such as demodulating a carrier signal, decrypting an encrypted signal, and/or decoding a compressed signal. Content delivery module 118 comprises one or more components that operate to deliver the media content produced by content generator 116 to a user. In an embodiment in which content generator 116 produces an audio signal, content delivery module 118 may include an audio signal processor that processes the audio signal so that it is in a form suitable for playback to a user and at least one speaker that converts the output of the audio signal processor into sound waves that may be perceived by the user. One example of such an embodiment will be described herein in reference to FIG. 3. In an embodiment in which content generator 116 produces an image, content delivery module 118 may include a display and an image processor that processes the image so that it is in a form suitable for rendering to the display. One example of such an embodiment will be described herein in reference to FIG. 5.

The manner by which media content is delivered to a user by content delivery module 118 is controlled, in part, by the value of at least one parameter, which is denoted “applied parameter value” in FIG. 1. For example, in an embodiment in which content delivery module 118 is configured to play back an audio signal to a user, the audio signal may be played back in accordance with a particular volume setting. As another example, in an embodiment in which content delivery module 118 is configured to render an image to a display, the brightness of the display may be controlled in accordance with a brightness setting. However, these examples are not intended to be limiting, and the parameter may conceivably comprise any of wide variety of parameters that can be used to control the delivery of media content. With respect to an audio signal, for example, the parameter may also comprise a bass setting, a treble setting, a balance setting, a fader setting, or the like. With respect to an image, for example, the parameter may also comprise a contrast setting, a white balance setting, a color balance setting, or the like.

Automatic parameter adjustment module 108 comprises a component that is configured to automatically apply adjustments to the value of the parameter used to control the delivery of media content by content delivery module 118. In particular, automatic parameter adjustment module 108 is configured to automatically apply adjustments to a base parameter value to produce an auto-adjusted parameter value. The base parameter value may represent, for example, a parameter value that is determined by analyzing the media content produced by content generator 116 (or is otherwise associated with the media content), a default parameter value that is associated with system 100, a user-specified parameter value, or a currently-applied parameter value, depending upon the implementation.

Automatic parameter adjustment module 108 is configured to automatically adjust the parameter based on one or more conditions that are discernable to module 108. In particular, automatic parameter adjustment module 108 is configured to automatically adjust the parameter based on at least a condition of an environment in which system 100 is operating. For example, the environmental condition may comprise a noise condition or a lighting condition. However, these examples are not intended to be limiting and the operation of automatic parameter adjustment module 108 may be based on numerous other environmental conditions. In system 100, environmental data is collected by one or more sensors 102 and then processed by a sensor data processor to produce information concerning the current environmental conditions. This environmental condition information is then provided to automatic parameter adjustment module 108 and used to calculate parameter adjustments.

In an embodiment, automatic parameter adjustment module 108 adjusts the value of the parameter on a periodic basis to ensure that the auto-adjusted parameter value is suitably correlated to current environmental conditions.

System 100 of FIG. 1 also provides a user interface 110 by which a user of system 100 can manually adjust the value of the parameter used to control the delivery of media content by content delivery module 118. Any of a wide variety of user interfaces may be used to perform this function including but not limited to mechanical user interfaces (e.g., buttons, dials, or the like), graphical user interfaces (e.g., graphical displays that may be interacted with using a keyboard, pointing device, touch screen or the like), audio user interfaces (e.g., voice-activation systems or the like), or any combination thereof The types of manual adjustments that may be made to the parameter may depend upon the type of parameter that is being adjusted. For example, if the parameter is volume, then the user may be allowed to increase or reduce the volume. As another example, if the parameter is brightness, then the user may be allowed to increase or reduce the brightness. However, these examples are not intended to be limiting.

User interface 110 is configured to detect user actions intended to adjust the parameter and to transmit information about the detected actions to manual parameter adjustment module 112. Manual parameter adjustment module 112 is configured to receive and interpret such information to determine a manual parameter adjustment to be applied to the value of the parameter.

As shown in FIG. 1, the value of the parameter that is ultimately applied to the media content that is delivered by content delivery module 118 is a combination of the auto-adjusted parameter value produced by automatic parameter adjustment module 108 and the manual parameter adjustments produced by manual parameter adjustment module 112. This configuration allows a user of system 100 to manually adjust the auto-adjusted parameter value if that parameter value is not providing the user with a satisfactory media experience (e.g., a satisfactory listening or viewing experience). The combination of the auto-adjusted parameter value and the manual parameter adjustments is performed by a combiner 114, which is intended to represent any suitable logic or combination for performing this function.

In one embodiment, the operation of automatic parameter adjustment module 108 can be turned off by a user (e.g., by interacting with user interface 110 or some other user interface). When automatic parameter adjustment module 108 has been turned off, adjustments to the base parameter value can still be implemented manually by the user via user interface 110.

As noted above, a user of system 100 can manually modify the auto-adjusted parameter value in a situation where the auto-adjusted parameter value is causing the delivery of media content by content delivery module 118 to be performed in a manner that is unsatisfactory to the user. However, it may be deemed undesirable to require a user to constantly manually adjust the parameter value to achieve a desired media experience. To address this issue, system 100 includes user preference learning module 106. User preference learning module 106 is connected to manual parameter adjustment module 112 and is configured to monitor user-implemented adjustments that are made to the parameter value after automatic adjustments have been made thereto by automatic parameter adjustment module 108. User preference learning module 106 is further configured to generate user preference information based on the monitoring. Generally speaking, the user preference information is intended to convey the magnitude of a manual adjustment a user would typically apply to an auto-adjusted parameter value under the particular environmental conditions that gave rise to the auto-adjusted parameter value. Such information can be obtained by accumulating historical data regarding manual adjustments made to the parameter by the user during a variety of different environmental conditions. Various examples of user preference information will be provided herein in reference to particular exemplary embodiments.

The user preference information generated by user preference learning module 106 is provided to automatic parameter adjustment module 108. Automatic parameter adjustment module 108 can then incorporate such information, along with information relating to the current environmental conditions, into the calculation of the auto-adjusted parameter value. In this way, automatic parameter adjustment module 108 can advantageously provide an auto-adjusted parameter value that accounts for user preferences regarding the parameter in various environmental conditions. In a sense, then, the user preference information constitutes a form of feedback that allows automatic parameter adjustment module 108 to automatically adjust the parameter in a manner that takes into account automatically-learned user preferences. This will enable automatic parameter adjustment module 108 to produce an auto-adjusted parameter value that will likely require little or no manual modification by the user in order for the user to achieve a satisfactory media experience.

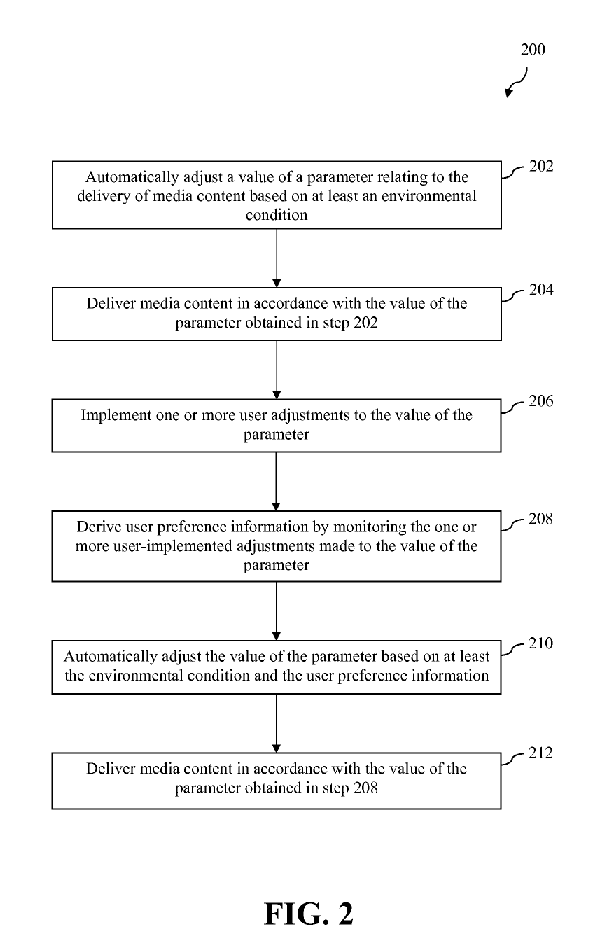

To further illustrate this concept, FIG. 2 depicts a flowchart 200 of a general method for performing automatic media content delivery parameter adjustment based on automatically-learned user preferences in accordance with an embodiment. The method of flowchart 200 will now be described in reference to various components of system 100 of FIG. 1. However, the method is not limited to that implementation and may be performed by other components or systems entirely.

As shown in FIG. 2, the method of flowchart 200 begins at step 202 in which automatic parameter adjustment module 108 automatically adjusts a value of a parameter relating to the delivery of media content based on at least an environmental condition. This step may entail, for example, modifying a base parameter value received by automatic parameter adjustment module 108 to produce an auto-adjusted parameter value. The degree of modification may be based on information concerning a current environmental condition as produced by sensor data processor 104.

At step 204, content delivery module 118 delivers media content to a user in accordance with the value of the parameter obtained by the automatic adjustment of step 202. Depending upon the implementation, this step may include providing the value of the parameter to content delivery module 118 for application to an audio signal, an image, or some other type of media content, or to a component used to render an audio signal, an image, or some other type of media content.

At step 206, a user makes one or more user-implemented adjustments to the value of the parameter after the auto-adjustment of step 202 by interacting with user interface 110. The user may make such adjustments, for example, to ensure that content delivery module 118 delivers media content in a manner that provides a more satisfactory media experience.

At step 208, user preference learning module 106 derives user preference information by monitoring the user-implemented adjustment(s) made to the value of the parameter during step 206. The monitoring may be achieved by obtaining information from manual parameter adjustment module 112 relating to the one or more user-implemented adjustment(s). As noted above, the user preference information may convey a magnitude of a manual adjustment that the user would typically apply to an auto-adjusted parameter value under the environmental conditions that gave rise to the auto-adjusted parameter value.

At step 210, automatic parameter adjustment module 108 receives the user preference information and automatically adjusts the value of the parameter based on at least the current environmental condition and the user preference information. This enables automatic parameter adjustment module to produce an auto-adjusted parameter value that accounts for both current environmental conditions and user preferences regarding the parameter in such conditions.

For example, assume that user preference learning module 106 determines over some period of time that a particular user will apply a manual adjustment of an average size, x, to the value of the parameter after the parameter has been auto-adjusted in accordance with an environmental condition y. In one embodiment of step 210, when environmental condition y is once again detected, automatic parameter adjustment module 108 will automatically adjust the parameter value in accordance with environmental condition y, but will also automatically apply the additional adjustment x to the value of the parameter so that the final auto-adjusted value of the parameter takes into account the typical behavior of the user with respect to modifying the auto-adjusted parameter during environmental condition y. The goal of this step is to require fewer or no manual adjustments by the user to achieve a satisfactory media experience.

At step 212, content delivery module 118 delivers media content in accordance with the value of the parameter obtained during step 210. Depending upon the implementation, this step may include providing the value of the parameter to content delivery module 118 for application to an audio signal, an image, or some other type of media content, or to a component used to render an audio signal, an image, or some other type of media content.

The foregoing described a general system and method for automatically adjusting a media content delivery parameter in a manner that takes into account automatically-learned user preferences. Specific example implementations of the general system and method will now be provided. A first example implementation described herein will relate to the automatic adjustment of a volume setting (or gain) applied to an audio signal produced by a system or device. A second example implementation described herein will relate to the automatic adjustment of a brightness setting applied to a display to which an image is rendered by a system or device. These examples are not intended to be limiting. Persons skilled in the relevant art(s) will readily appreciate that the concepts described herein can be broadly applied to the automatic adjustment of any parameter used to control or modify the delivery of media content.

### C. Example System and Method for Adjusting a Volume Setting Based on Automatically-Learned User Preferences

FIG. 3 is a block diagram of an example system 300 that performs automatic volume adjustment based on automatically-learned user preferences in accordance with an embodiment of the present invention. System 300 is intended to represent a specific example implementation of system 100 described above in reference to FIG. 1. As will be appreciated by persons skilled in the relevant art(s) based on the teachings provided herein, system 300 may be implemented as part of any system or device that is capable of delivering audio content to a user, including but not limited to audio systems implemented in cars, homes, or other environments, home theater systems, video gaming systems or consoles, personal computer systems having audio delivery capabilities, and many portable user devices that produce audio output including laptop computers, tablet computers, cellular telephones, smart phones, personal media players, personal digital assistants, Bluetooth® headsets, and the like. As shown in FIG. 3, system 300 includes one or more microphones 302, a microphone data processor 304, a user preference learning module 306, an automatic volume adjustment module 308, a user interface 310, a manual volume adjustment module 312, a combiner 314, an audio signal generator 316, an audio signal processor 318 and a speaker 320. Each of these elements will now be described.

Audio signal generator 316 comprises one or more components that operate to produce an audio signal for presentation to a user. Depending upon the implementation, audio signal generator 316 may obtain the audio signal from a system or device, such as a storage system or device, that is directly connected to or integrated with system 300 or from a system or device that is connected to system 300 via a network, such as a local or wide area data network or a telecommunications network. Depending upon the implementation, producing the audio signal may comprise performing operations such as demodulating a carrier signal, decrypting an encrypted signal, and/or decoding a compressed signal. Audio signal generator 316 is one example of content generator 116 as described above in reference to system 100 of FIG. 1.

Audio signal processor 318 comprises a component that processes the audio signal produced by audio signal generator 316 so that it is in a form suitable for playback. Speaker 320 converts the output of audio signal processor 318 into sound waves that may be perceived by a user. Although only one speaker 320 is shown in FIG. 3 for the sake of simplicity, it is to be understood that system 300 may include any number of speakers. Taken together, audio signal processor 318 and speaker 320 provide one example of content delivery module 118 as described above in reference to system 100 of FIG. 1.

The manner by which an audio signal is processed for playback by audio signal processor 318 is controlled, in part, by a volume setting, which is denoted “applied volume” in FIG. 3. The volume setting may comprise for example, a gain to be applied to the audio signal by audio signal processor 318 or may comprise a parameter from which a gain to be applied to the audio signal may be derived. Although system 300 is described as playing back a single audio signal in accordance with a volume setting, it is to be understood that system 300 may play back any number of audio signals (e.g., audio signals corresponding to different channels in a multi-channel audio system) in accordance with a single volume setting or in accordance with different volume settings. Each of the different volume settings may be automatically adjusted in accordance with the techniques described herein.

Automatic volume adjustment module 308 comprises a component that is configured to automatically apply adjustments to the volume setting that is used by audio signal processor 318. In particular, automatic volume adjustment module 308 is configured to automatically apply adjustments to a base volume setting to produce an auto-adjusted volume setting. The base volume setting may represent, for example, a base gain that is to be applied to the audio signal. For example, the base gain may comprise a default gain value intended to provide a comfortable listening experience in the absence of environmental noise. Additionally or alternatively, the base gain may comprise a gain amount necessary to bring the audio signal to a nominal level. However, these examples are not intended to be limiting, and the base volume setting may represent other values that can be used to control the volume of an audio signal. Automatic volume adjustment module 308 is one example of automatic parameter adjustment module 108 described above in reference to system 100 of FIG. 1.

Automatic volume adjustment module 308 is configured to automatically adjust the volume setting based on one or more conditions that are discernable to module 308. In particular, automatic volume adjustment module 308 is configured to automatically adjust the volume setting based on at least a noise condition of an environment in which system 300 is operating. For example, the environmental noise condition may comprise an ambient noise level of the environment in which system 300 is operating. However, this is only one example and other types of environmental noise conditions may be considered including conditions associated with different types of stationary noise and non-stationary noise (e.g., babble noise, street noise, musical noise, or the like).

In system 300, sound wave data is collected by one or more microphones 302 and then processed by microphone data processor 304 to produce information concerning the current environmental noise conditions. This environmental noise information is then provided to automatic volume adjustment module 308 and used to calculate volume adjustments. Microphone(s) 302 and microphone data processor 304 constitute examples of sensor(s) 102 and sensor data processor 104, respectively, as previously described in reference to system 100 of FIG. 1.

In an embodiment, automatic volume adjustment module 308 adjusts the value of the volume setting on a periodic basis to ensure that the auto-adjusted volume setting is suitably correlated to current environmental noise conditions. For example, the volume setting may be automatically adjusted on a periodic basis that is correlated to the frame rate of the audio signal being played back by audio signal processor 318, such that an updated volume setting is generated for each frame of the audio signal. However, this is only an example, and automatic volume adjustment module 308 may adjust the value of the volume setting at a rate that is determined or defined in accordance with other factors.

System 300 of FIG. 3 also provides a user interface 310 by which a user of system 300 can manually adjust the value of the volume setting used to control the processing of the audio signal by audio signal processor 318. User interface 310 is intended to represent one example of user interface 110 described above in reference to FIG. 1 and may be implemented in a like manner to that component. User interface 310 is configured to detect user actions intended to adjust the volume setting (e.g., increasing or reducing the volume setting) and to transmit information about the detected actions to manual volume adjustment module 312. Manual volume adjustment module 312 is configured to receive and interpret such information to determine a manual volume adjustment to be applied to the volume setting.

As shown in FIG. 3, the volume setting that is ultimately applied to the audio signal that is processed by audio signal processor 318 is a combination of the auto-adjusted volume setting produced by automatic volume adjustment module 308 and the manual volume adjustments produced by manual volume adjustment module 312. This configuration allows a user of system 300 to manually adjust the auto-adjusted volume setting if that setting is not providing the user with a satisfactory listening experience (e.g., if the played-back audio signal is too soft or too loud). The combination of the auto-adjusted volume setting and the manual volume adjustments is performed by a combiner 314, which is one example of combiner 114 described above in reference to system 100 of FIG. 1.

In one embodiment, the operation of automatic volume adjustment module 308 can be turned off by a user (e.g., by interacting with user interface 310 or some other user interface). When automatic volume adjustment module 308 has been turned off, adjustments to the base volume setting can still be implemented manually by the user via user interface 310.

As noted above, a user of system 300 can manually modify the auto-adjusted volume setting in a situation where the level at which the audio signal is played back by audio signal processor 318 and speaker 320 is determined to be unsatisfactory to the user. However, it may be deemed undesirable to require a user to constantly manually adjust the volume setting to achieve a desired listening experience. To address this issue, system 300 includes user preference learning module 306, which is one example of user preference learning module 106 described above in reference to system 100 of FIG. 1. User preference learning module 306 is connected to manual volume adjustment module 312 and is configured to monitor user-implemented adjustments that are made to the volume setting after automatic adjustments have been made thereto by automatic volume adjustment module 308. User preference learning module 306 is further configured to generate user preference information based on the monitoring. Generally speaking, the user preference information is intended to convey the magnitude of a manual adjustment a user would typically apply to an auto-adjusted volume setting under the particular environmental noise conditions that gave rise to the auto-adjusted volume setting. Such information can be obtained by accumulating historical data regarding manual adjustments made to the volume setting by the user during a variety of different environmental noise conditions.

The user preference information generated by user preference learning module 306 is provided to automatic volume adjustment module 308. Automatic volume adjustment module 308 can then incorporate such information, along with information relating to the current environmental noise conditions, into the calculation of the auto-adjusted volume setting. In this way, automatic volume adjustment module 308 can advantageously provide an auto-adjusted volume setting that accounts for user preferences regarding volume in various environmental noise conditions. In a sense, then, the user preference information constitutes a form of feedback that allows automatic volume adjustment module 308 to automatically adjust the volume in a manner that takes into account automatically-learned user preferences. This will enable automatic volume adjustment module 308 to produce an auto-adjusted volume setting that will likely require little or no manual modification by the user in order for the user to achieve a satisfactory listening experience.

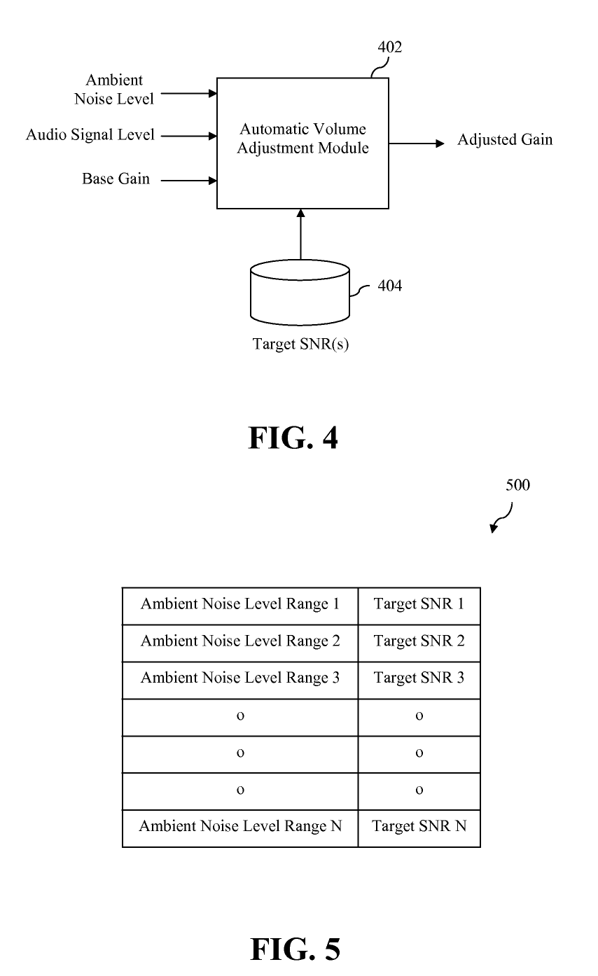

FIG. 4 is a block diagram of an automatic volume adjustment module 402, which is one example of automatic volume adjustment module 308 described above in reference to system 300 of FIG. 3. In the embodiment depicted in FIG. 4, automatic volume adjustment module 402 is configured to receive a base gain to be applied to the audio signal processed by audio signal processor 318 and to automatically adjust the base gain to produce an adjusted gain. In one embodiment, the base gain comprises a default gain that provides a comfortable listening level in quiet conditions for a nominal level signal. Note that in some embodiments, the default gain may be zero. In a further embodiment, the base gain may also comprise a gain output by an automatic gain control (AGC) module based on an analysis of the audio signal, which may be referred to as an AGC gain. The AGC gain may be an amount of gain needed to bring the audio signal to a nominal level. In still further embodiments, the base gain may comprise the sum of a default gain and an AGC gain.

As shown in FIG. 4, automatic volume adjustment module 402 is also configured to receive an ambient noise level and an audio signal level. The ambient noise level may be periodically provided by sensor data processor 304 based on data collected from microphone(s) 302. The audio signal level is intended to represent a current estimate of the level of the audio signal being processed by audio signal processor 318 and may be provided by a signal level estimator (not shown in FIG. 3) that is included within system 300. There are various methods known in the art for estimating the level of an audio signal and any of these methods may be used to provide the audio signal level that is input to automatic volume adjustment module 402.

Given the base gain, audio signal level and ambient noise level, automatic volume adjustment module 402 determines a current signal-to-noise ratio (SNR) in accordance with the equation:

currentSNR=base_gain+signal_level−noise_level+cal

wherein currentSNR represents the current SNR, base_gain represents the base gain, signal_level represents the audio signal level, noise_level represents the ambient noise level and cal represents a calibration term to ensure the SNR reflects the auditory experience by the user. The foregoing calculation is performed in the log domain, although persons skilled in the art will appreciate that an equivalent calculation may be performed in the linear domain, or possibly in a different domain.

As further shown in FIG. 4, automatic volume adjustment module 402 also communicates with a memory 404 that stores one or more target SNRs. Memory 404 is part of system 300. In one implementation, memory 404 stores only a single target SNR. The single target SNR represents a desired minimum SNR between the audio signal being played back and the ambient background noise. Automatic volume adjustment module 402 determines if the target SNR exceeds the current SNR and, if so, adjusts the base gain by an amount necessary to achieve the target SNR. Note that automatic volume adjustment module 402 may also take into account other factors when determining the size of the adjustment to the base gain, such as a predefined maximum amount of gain adjustment that can be applied by module 308 and/or constraints on periodic gain adjustment changes (e.g., step sizes) to ensure that changes occur gradually.

In an alternate embodiment, memory 404 stores multiple target SNRs, wherein each target SNR is associated with a particular range of ambient noise levels. For example, FIG. 5 depicts a look-up table 500 that may be stored in memory 404 in accordance with such an embodiment. As shown in FIG. 5, look-up table 500 stores a target SNR 1-N associated with corresponding ambient noise level ranges 1-N. In accordance with such an embodiment, automatic volume adjustment module 402 selects the target SNR by determining which of ambient noise level ranges 1-N the current ambient noise level falls into and then selecting the target SNR associated with the relevant ambient noise range. Automatic volume adjustment module 402 then determines the amount by which the base gain should be adjusted to achieve the selected target SNR by comparing the selected target SNR to the current SNR in a like manner to that described above for an embodiment with only a single target SNR. Using multiple target SNRs for different ambient noise level ranges advantageously allows for fine-tuning of the automatic volume adjustment feature for different ambient noise levels.

In accordance with an embodiment, the target SNR(s) stored in memory 404 are initialized during manufacture to some default setting. These default target SNRs are then used by automatic volume adjustment module 308 to automatically adjust the volume setting in accordance with current ambient noise levels. If the auto-adjusted volume setting is not satisfactory to the user of system 300, then the user may utilize user interface 310 to increase or reduce the volume setting. User preference learning module 306 may be configured to monitor these user-implemented changes and then adjust the target SNR(s) based on such changes. For example, if the default target SNR for a given ambient noise level range is 15 dB and history has shown that a user typically reduces the auto-adjusted volume setting by 5 dB when the ambient noise level is in the given range, then user preference learning module may reduce the target SNR for the given range to 10 dB. Thus, in one embodiment, user preference learning module 306 may monitor user-implemented changes to the auto-adjusted volume setting across all ambient noise level ranges and generate user-specific target SNRs for subsequent use by automatic volume adjustment module 308.

Various methods may be used to modify the target SNR associated with a particular ambient noise level range based on user-implemented volume adjustments. For example, a long-term average of user-implemented volume adjustments may be maintained for each ambient noise level range. The long-term average for each ambient noise level range may then be added to the corresponding default target SNR for each ambient noise level range to generate a user-specific target SNR for each ambient noise level range.

Of course, the generation of user-specific target SNRs as described above represents only one approach to deriving user preference information for use in automatically adjusting a volume setting. Persons skilled in the relevant art(s) will readily appreciate that a wide variety of other approaches may be used to derive such user preference information based on the monitoring of user-implemented volume setting changes. Such other approaches are also within the scope and spirit of the present invention.

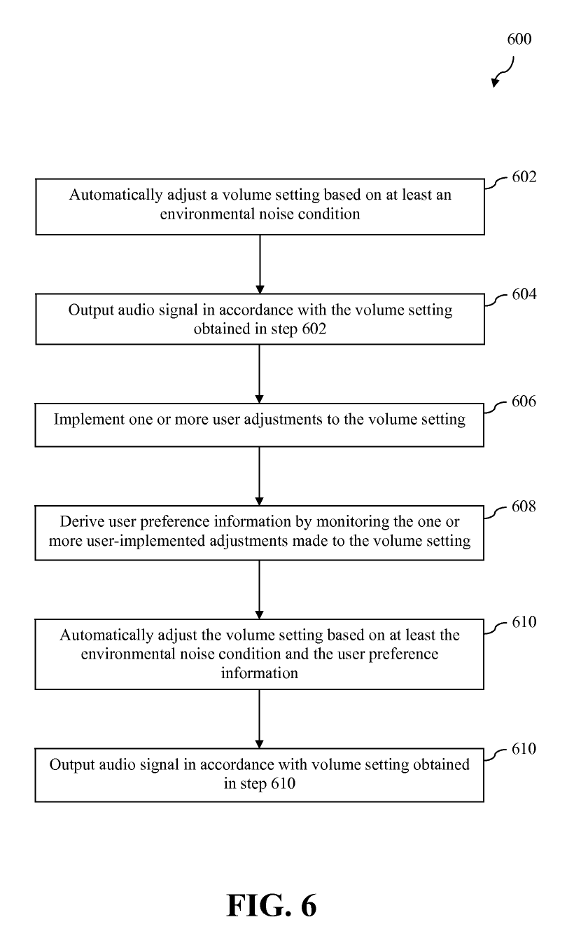

A flowchart 600 of an example method for performing automatic volume adjustment based on automatically-learned user preferences will now be described with reference to FIG. 6. The method of flowchart 600 will be described in reference to various components system 300 of FIG. 3. However, the method is not limited to that implementation and may be performed by other components or systems entirely.

As shown in FIG. 6, the method of flowchart 600 begins at step 602 in which automatic volume adjustment module 308 automatically adjusts a volume setting based on at least an environmental noise condition. This step may entail, for example, modifying a base volume setting received by automatic volume adjustment module 308 to produce an auto-adjusted volume setting. The degree of modification may be based on information concerning a current environmental noise condition as produced by microphone data processor 304. In an embodiment in which the environmental noise condition comprises an ambient noise level, step 602 may include automatically adjusting the volume setting to achieve a default target SNR given the ambient noise level.

At step 604, audio signal processor 318 outputs an audio signal to speaker 320 in accordance with the volume setting obtained during step 602. This step may comprise, for example, applying an automatically-adjusted gain to an audio signal being processed by audio signal processor 318. The application of the gain may occur before, during or after other modifications that may be applied to the audio signal by audio signal processor 318. For example, audio signal processor 318 may apply the automatically-adjusted gain to the audio signal before, during or after performing other functions that change the level of the audio signal and/or other features of the audio signal. Such functions may include, for example and without limitation, filtering, spectral shaping, compression, hard clipping or soft clipping of the audio signal. Such functions may also include, for example and without limitation, the application of other gains (both positive and negative) to the audio signal.

At step 606, a user makes one or more user-implemented adjustments to the volume setting after the auto-adjustment of step 602 by interacting with user interface 310. For example, the user may increase or reduce the volume setting. The user may make such adjustments, for example, to ensure that audio signal processor 318 and speaker 320 deliver an audio signal in a manner that provides a more satisfactory listening experience.

At step 608, user preference learning module 306 derives user preference information by monitoring the user-implemented adjustment(s) made to the volume setting during step 606. The monitoring may be achieved by obtaining information from manual volume adjustment module 312 relating to the one or more user-implemented adjustment(s). As noted above, the user preference information may convey a magnitude of a manual adjustment that the user would typically apply to an auto-adjusted volume setting under the environmental noise conditions that gave rise to the auto-adjusted volume setting. In one embodiment, step 608 includes deriving one or more user-specific target SNRs to be used in performing automatic adjustment of the volume setting. Where multiple user-specific target SNRs are derived, each ratio may be associated with a particular range of ambient noise levels as discussed above.

At step 610, automatic volume adjustment module 308 receives the user preference information and automatically adjusts the volume setting based on at least the current environmental noise condition and the user preference information. This enables automatic volume adjustment module 610 to produce an auto-adjusted volume setting that accounts for both current environmental noise conditions and user preferences regarding the volume setting in such conditions. In one embodiment, step 610 includes automatically adjusting the volume setting to achieve a user-specific target SNR given an ambient noise level. In an embodiment in which multiple user-specific target SNRs are maintained, this step may include selecting one of the user-specific target SNRs based on the ambient noise level and automatically adjusting the volume setting to achieve the selected user-specific target SNR given the ambient noise level.

At step 612, audio signal processor 318 outputs an audio signal to speaker 320 in accordance with the volume setting obtained during step 610. Like step 604, this step may comprise, for example, applying an automatically-adjusted gain to an audio signal being processed by audio signal processor 318. As also noted above with respect to step 604, the application of the gain may occur before, during or after other modifications that may be applied to the audio signal by audio signal processor 318.

### D. Example System and Method for Adjusting a Brightness Setting Based on Automatically-Learned User Preferences

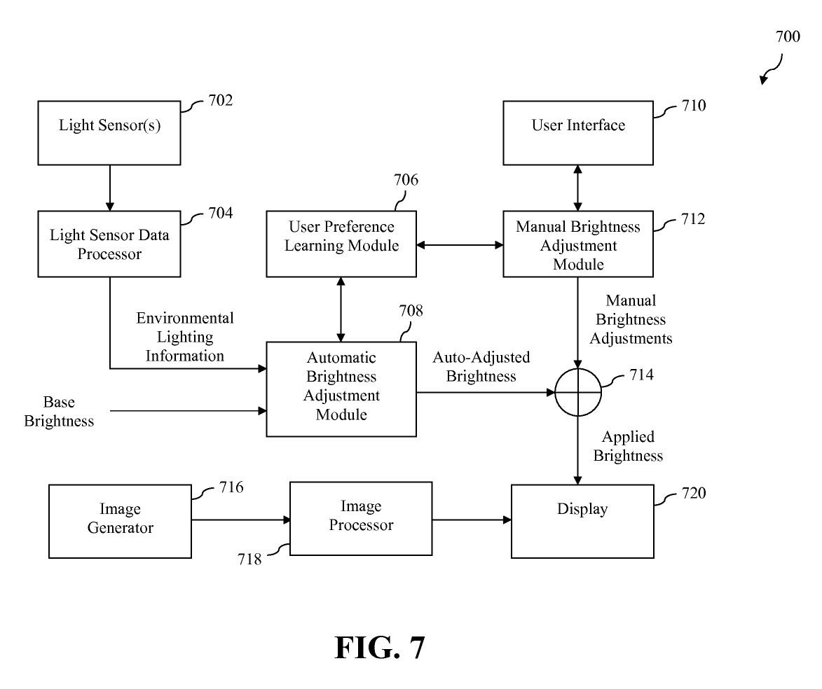

FIG. 7 is a block diagram of an example system 700 that performs automatic brightness adjustment based on automatically-learned user preferences in accordance with an embodiment of the present invention. System 700 is intended to represent a specific example implementation of system 100 described above in reference to FIG. 1. As will be appreciated by persons skilled in the relevant art(s) based on the teachings provided herein, system 700 may be implemented as part of any system or device that is capable of delivering image content to a user, including but not limited to televisions, home theater systems, personal computer systems, and many portable user devices that include displays such as laptop computers, tablet computers, cellular telephones, smart phones, personal media players, personal digital assistants, and the like. As shown in FIG. 7, system 700 includes one or more light sensors 702, a light sensor data processor 704, a user preference learning module 706, an automatic brightness adjustment module 708, a user interface 710, a manual brightness adjustment module 712, a combiner 714, an image generator 716, an image processor 718 and a display 720. Each of these elements will now be described.

Image generator 716 comprises one or more components that operate to produce an image for presentation to a user. The image may comprise, for example and without limitation, a static image or an image in a series of images that comprise video content, an animation, or the like. Depending upon the implementation, image generator 716 may obtain the image from a system or device, such as a storage system or device, that is directly connected to or integrated with system 700 or from a system or device that is connected to system 700 via a network, such as a local or wide area data network or a telecommunications network. Depending upon the implementation, producing the image may comprise performing operations such as demodulating a carrier signal, decrypting an encrypted signal, and/or decoding a compressed signal. Image generator 716 is one example of content generator 116 as described above in reference to system 100 of FIG. 1.

Image processor 718 comprises a component that renders the image produced by image generator 718 to display 720 for viewing by a user. Taken together, image processor 718 and display 720 provide one example of content delivery module 118 as described above in reference to system 100 of FIG. 1.

The brightness of display 720 is controlled, at least in part, by a brightness setting, which is denoted “applied brightness” in FIG. 7. Depending upon the implementation, the brightness setting may be used to control the brightness of display 720 by controlling the brightness of a backlighting component within display 720 or by controlling the intensity of LCD pixels within display 720, although these are only examples and other means known in the art for controlling the brightness of a display may be used.

Automatic brightness adjustment module 708 comprises a component that is configured to automatically apply adjustments to the brightness setting that is applied to display 720. In particular, automatic brightness adjustment module 708 is configured to automatically apply adjustments to a base brightness setting to produce an auto-adjusted brightness setting. Automatic brightness adjustment module 708 is one example of automatic parameter adjustment module 108 described above in reference to system 100 of FIG. 1.

Automatic brightness adjustment module 708 is configured to automatically adjust the brightness setting based on one or more conditions that are discernable to module 708. In particular, automatic brightness adjustment module 708 is configured to automatically adjust the brightness setting based on at least a lighting condition of an environment in which system 700 is operating. For example, the environmental lighting condition may comprise an ambient light level of the environment in which system 700 is operating. However, this is only one example and other types of environmental lighting conditions may be considered.

In system 700, lighting data is collected by one or more light sensors 702 and then processed by light sensor data processor 704 to produce information concerning the current environmental lighting conditions. This environmental lighting information is then provided to automatic brightness adjustment module 708 and used to calculate brightness adjustments. Light sensor(s) 702 and light sensor data processor 704 constitute examples of sensor(s) 102 and sensor data processor 104, respectively, as previously described in reference to system 100 of FIG. 1.

In an embodiment, automatic brightness adjustment module 708 adjusts the value of the brightness setting on a periodic basis to ensure that the auto-adjusted brightness setting is suitably correlated to current environmental lighting conditions.

System 700 of FIG. 7 also provides a user interface 710 by which a user of system 700 can manually adjust the value of the brightness setting used to control the brightness of display 720. User interface 710 is intended to represent one example of user interface 110 described above in reference to FIG. 1 and may be implemented in a like manner to that component. User interface 710 is configured to detect user actions intended to adjust the brightness setting (e.g., increasing or reducing the brightness setting) and to transmit information about the detected actions to manual brightness adjustment module 712. Manual brightness adjustment module 712 is configured to receive and interpret such information to determine a manual brightness adjustment to be applied to the brightness setting.

As shown in FIG. 7, the brightness setting that is ultimately provided to display 720 is a combination of the auto-adjusted brightness setting produced by automatic brightness adjustment module 708 and the manual brightness adjustments produced by manual brightness adjustment module 712. This configuration allows a user of system 700 to manually adjust the auto-adjusted brightness setting if that setting is not providing the user with a satisfactory viewing experience (e.g., if the images rendered to display 720 are too bright or too dim). The combination of the auto-adjusted brightness setting and the manual brightness adjustments is performed by a combiner 714, which is one example of combiner 114 described above in reference to system 100 of FIG. 1.

In one embodiment, the operation of automatic brightness adjustment module 708 can be turned off by a user (e.g., by interacting with user interface 710 or some other user interface). When automatic brightness adjustment module 708 has been turned off, adjustments to the base brightness setting can still be implemented manually by the user via user interface 710.

As noted above, a user of system 700 can manually modify the auto-adjusted brightness setting in a situation where the brightness of display 720 is determined to be unsatisfactory to the user. However, it may be deemed undesirable to require a user to constantly manually adjust the brightness setting to achieve a desired viewing experience. To address this issue, system 700 includes user preference learning module 706, which is one example of user preference learning module 106 described above in reference to system 100 of FIG. 1. User preference learning module 706 is connected to manual brightness adjustment module 712 and is configured to monitor user-implemented adjustments that are made to the brightness setting after automatic adjustments have been made thereto by automatic brightness adjustment module 708. User preference learning module 706 is further configured to generate user preference information based on the monitoring. Generally speaking, the user preference information is intended to convey the magnitude of a manual adjustment a user would typically apply to an auto-adjusted brightness setting under the particular environmental lighting conditions that gave rise to the auto-adjusted brightness setting. Such information can be obtained by accumulating historical data regarding manual adjustments made to the brightness setting by the user during a variety of different environmental lighting conditions.

The user preference information generated by user preference learning module 706 is provided to automatic brightness adjustment module 708. Automatic brightness adjustment module 708 can then incorporate such information, along with information relating to the current environmental lighting conditions, into the calculation of the auto-adjusted brightness setting. In this way, automatic brightness adjustment module 708 can advantageously provide an auto-adjusted brightness setting that accounts for user preferences regarding brightness in various environmental lighting conditions. In a sense, then, the user preference information constitutes a form of feedback that allows automatic brightness adjustment module 708 to automatically adjust the brightness in a manner that takes into account automatically-learned user preferences. This will enable automatic brightness adjustment module 708 to produce an auto-adjusted brightness setting that will likely require little or no manual modification by the user in order for the user to achieve a satisfactory viewing experience.

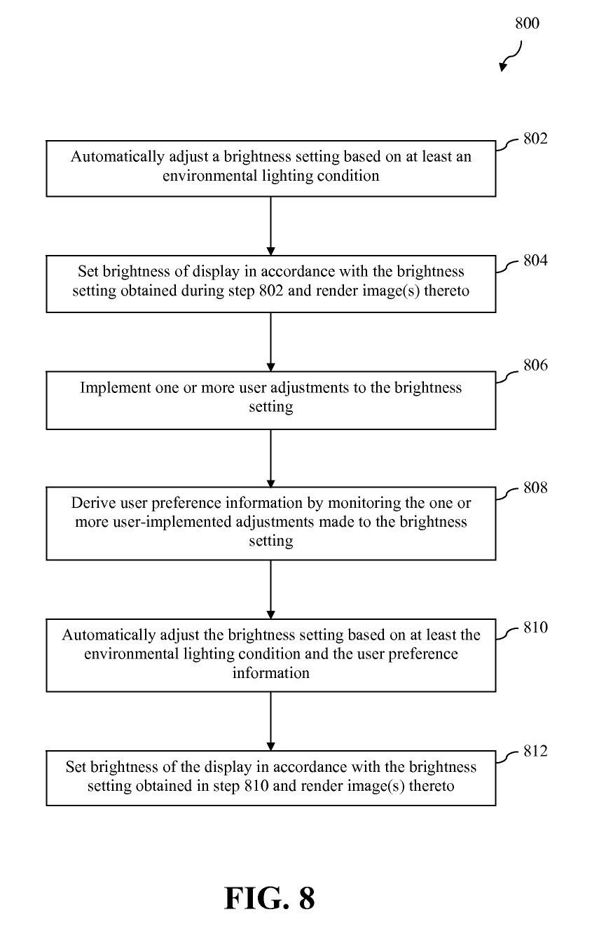

A flowchart 800 of an example method for performing automatic brightness adjustment based on automatically-learned user preferences will now be described with reference to FIG. 8. The method of flowchart 800 will be described in reference to various components system 700 of FIG. 7. However, the method is not limited to that implementation and may be performed by other components or systems entirely.

As shown in FIG. 8, the method of flowchart 800 begins at step 802 in which automatic brightness adjustment module 708 automatically adjusts a brightness setting based on at least an environmental lighting condition. This step may entail, for example, modifying a base brightness setting received by automatic brightness adjustment module 708 to produce an auto-adjusted brightness setting. The degree of modification may be based on information concerning a current environmental lighting condition as produced by light sensor data processor 704. In one embodiment, the environmental lighting condition comprises an ambient light level.

At step 804, the brightness of display 720 is set in accordance with the brightness setting obtained during step 802 and one or more images are then rendered to display 720.

At step 806, a user makes one or more user-implemented adjustments to the brightness setting after the auto-adjustment of step 802 by interacting with user interface 710. For example, the user may increase or reduce the brightness setting. The user may make such adjustments, for example, to ensure that images rendered to display 720 are perceived at a desired brightness, thereby providing a more satisfactory viewing experience.

At step 808, user preference learning module 706 derives user preference information by monitoring the user-implemented adjustment(s) made to the brightness setting during step 806. The monitoring may be achieved by obtaining information from manual brightness adjustment module 712 relating to the one or more user-implemented adjustment(s). As noted above, the user preference information may convey a magnitude of a manual adjustment that the user would typically apply to an auto-adjusted brightness setting under the environmental lighting conditions that gave rise to the auto-adjusted brightness setting.

At step 810, automatic brightness adjustment module 708 receives the user preference information and automatically adjusts the brightness setting based on at least the current environmental lighting condition and the user preference information. This enables automatic brightness adjustment module 810 to produce an auto-adjusted brightness setting that accounts for both current environmental lighting conditions and user preferences regarding the brightness setting in such conditions.

At step 812, the brightness of display 720 is set in accordance with the brightness setting obtained during step 810 and the one or more images are then rendered to display 720.

### E. Example Multi-User Embodiment

In accordance with one embodiment, user preference learning module 106 is configured to monitor user-implemented adjustments that are made to a parameter value after automatic adjustments have been made thereto by automatic parameter adjustment module 108 and to determine whether such user-implemented adjustments are associated with one of a plurality of users. In accordance with such an embodiment, user preference learning module 106 is further configured to generate user preference information for each of the plurality of users based on the user-implemented adjustments associated with each user. This advantageously allows system 100 to perform automatic parameter adjustments based on different user preferences associated with different users. Such an implementation may be particularly desirable in an embodiment in which system 100 is a system that is designed for use by multiple users (e.g., a car stereo, television, or the like).

To achieve this, system 100 must provide a means for determining when a particular user from among a plurality of users is using system 100. A variety of technologies are available in the art for making such a determination. For example, for devices equipped with a microphone (such as telephony devices), automatic speech recognition technology may be used. For devices equipped with a camera, face recognition technology or the like may be used. As another example, biometric sensors may be provided on the device to obtain biometric data useful for identifying a user or distinguishing between users. As another example, user interface 110 may be equipped with a means by which a user can explicitly identify themselves to system 100 (e.g., by logging in, loading a particular profile, or the like). Another example for application to a car stereo includes tying user specific learned settings to the specific key used to open doors, unlock, or operate vehicle. This is similar to how certain cars adjust the driver's seat to a position (stored in memory) associated with individual keys according to which key is used to unlock the vehicle. In certain embodiments, user preference learning module 106 may also be configured to detect patterns of manual adjustments made to the auto-adjusted parameter and to associate distinct patterns with different users.

### F. Example Computer System Implementation

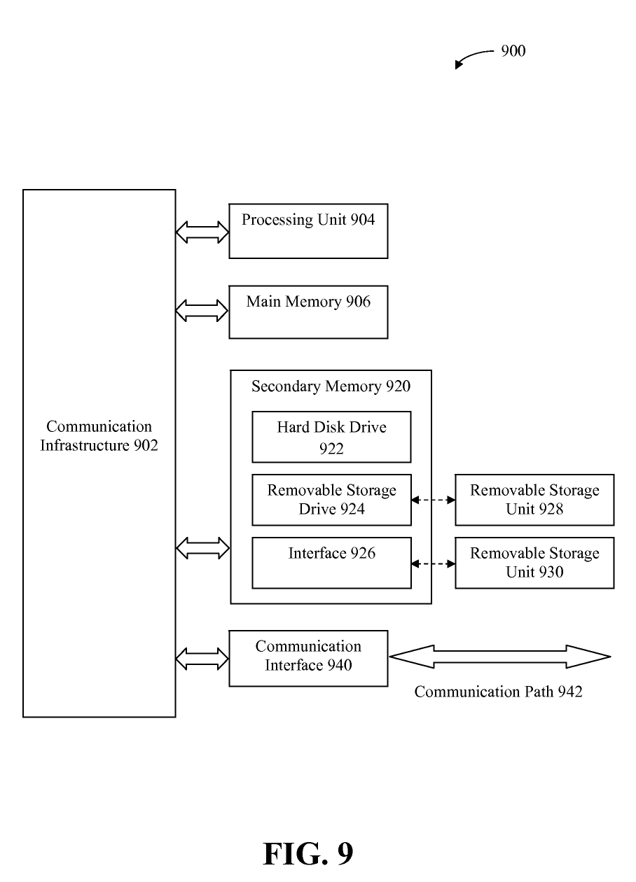

The following description of a general purpose computer system is provided for the sake of completeness. The present invention can be implemented in hardware, or as a combination of software and hardware. Consequently, the invention may be implemented in the environment of a computer system or other processing system. An example of such a computer system 900 is shown in FIG. 9.

Computer system 900 includes a processing unit 904 that includes one or more processors or processor cores. Processing unit 904 is connected to a communication infrastructure 902 (for example, a bus or network). Various software implementations are described in terms of this exemplary computer system. After reading this description, it will become apparent to a person skilled in the relevant art(s) how to implement the invention using other computer systems and/or computer architectures.

Computer system 900 also includes a main memory 906, preferably random access memory (RAM), and may also include a secondary memory 920. Secondary memory 920 may include, for example, a hard disk drive 922 and/or a removable storage drive 924, representing a floppy disk drive, a magnetic tape drive, an optical disk drive, or the like. Removable storage drive 924 reads from and/or writes to a removable storage unit 928 in a well known manner. Removable storage unit 928 represents a floppy disk, magnetic tape, optical disk, or the like, which is read by and written to by removable storage drive 924. As will be appreciated by persons skilled in the relevant art(s), removable storage unit 928 includes a computer usable storage medium having stored therein computer software and/or data.

In alternative implementations, secondary memory 920 may include other similar means for allowing computer programs or other instructions to be loaded into computer system 900. Such means may include, for example, a removable storage unit 930 and an interface 926. Examples of such means may include a program cartridge and cartridge interface (such as that found in video game devices), a removable memory chip (such as an EPROM, or PROM) and associated socket, and other removable storage units 930 and interfaces 926 which allow software and data to be transferred from removable storage unit 930 to computer system 900.

Computer system 900 may also include a communications interface 940. Communications interface 940 allows software and data to be transferred between computer system 900 and external devices. Examples of communications interface 940 may include a modem, a network interface (such as an Ethernet card), a communications port, a PCMCIA slot and card, etc. Software and data transferred via communications interface 940 are in the form of signals which may be electronic, electromagnetic, optical, or other signals capable of being received by communications interface 940. These signals are provided to communications interface 940 via a communications path 942. Communications path 942 carries signals and may be implemented using wire or cable, fiber optics, a phone line, a cellular phone link, an RF link and other communications channels.

As used herein, the terms “computer program medium” and “computer usable medium” are used to generally refer to media such as removable storage units 928 and 930 or a hard disk installed in hard disk drive 922. These computer program products are means for providing software to computer system 900.

Computer programs (also called computer control logic) are stored in main memory 906 and/or secondary memory 920. Computer programs may also be received via communications interface 940. Such computer programs, when executed, enable the computer system 900 to implement the present invention as discussed herein. In particular, the computer programs, when executed, enable processing unit 904 to implement the functions of the present invention, such as any of the steps of flowcharts 200, 600 or 800 as described elsewhere herein or any of the functions attributed to the modules included within systems 100, 300 and 700 as described elsewhere herein. Accordingly, such computer programs represent controllers of the computer system 900. Where the invention is implemented using software, the software may be stored in a computer program product and loaded into computer system 900 using removable storage drive 924, interface 926, or communications interface 940.

In another embodiment, features of the invention are implemented primarily in hardware using, for example, hardware components such as application-specific integrated circuits (ASICs) and gate arrays. Implementation of a hardware state machine so as to perform the functions described herein will also be apparent to persons skilled in the relevant art(s).

### F. Conclusion

While various embodiments of the present invention have been described above, it should be understood that they have been presented by way of example only, and not limitation. For example, although specific embodiments of the invention described herein automatically adjust a value of a parameter relating to the delivery of audio or image content based on both environmental conditions and on automatically-learned user preference data, it is to be understood that the invention may also be used to adjust the value of a parameter relating to the delivery of other types of media content. For example, and without limitation, such other types of media content may include haptic content. As will be appreciated by persons skilled in the relevant art(s) such haptic content may include tactile output or feedback that takes advantage of a user's sense of touch by applying forces, vibrations and/or motions to the user. The parameter used to control such haptic content may include for example a parameter that controls the type, duration, or force of such tactile output or feedback.

It will be understood by those skilled in the relevant art(s) that various changes in form and details may be made to the embodiments of the present invention described herein without departing from the spirit and scope of the invention as defined in the appended claims. Accordingly, the breadth and scope of the present invention should not be limited by any of the above-described exemplary embodiments, but should be defined only in accordance with the following claims and their equivalents.

What is claimed is:

1. A system, comprising:
a content delivery module that is configured to deliver media content to a user in accordance with a value of a content delivery parameter;
an automatic parameter adjustment module that is configured to automatically adjust the value of the content delivery parameter based on at least an environmental condition; and
a user preference learning module that is configured to derive user preference information by monitoring one or more user-implemented adjustments made to the value of the content delivery parameter after the automatic adjustment thereof by the automatic parameter adjustment module and to provide the user preference information to the automatic parameter adjustment module;
wherein the automatic parameter adjustment module is further configured to automatically adjust the value of the content delivery parameter based on at least the environmental condition and the user preference information.

2. The system of claim 1, wherein:
the content delivery module comprises an audio processing module that is configured to output an audio signal at a volume setting;
the automatic parameter adjustment module comprises an automatic volume adjustment module that is configured to automatically adjust the value of the volume setting based on at least an environmental noise condition;
the user preference learning module is configured to derive the user preference information by monitoring one or more user-implemented adjustments made to the volume setting after the automatic adjustment thereof by the automatic volume adjustment module; and
wherein the automatic volume adjustment module is further configured to automatically adjust the volume setting based on at least the environmental noise condition and the user preference information.

3. The system of claim 2, further comprising:
one or more microphones; and
a microphone data processor that is configured to determine the environmental noise condition by processing data produced by the one or more microphones.

4. The system of claim 2, wherein the automatic volume adjustment module is configured to automatically adjust the value of the volume setting based on at least an ambient noise level.

5. The system of claim 4, wherein the automatic volume adjustment module is configured to automatically adjust the volume setting to achieve a default target signal-to-noise ratio given the ambient noise level;
wherein the user preference learning module is configured to derive a user-specific target signal-to-noise ratio by monitoring the one or more user-implemented adjustments made to the volume setting after the automatic adjustment thereof by the automatic volume adjustment module and to provide the user-specific target signal-to-noise ratio to the automatic volume adjustment module; and
wherein the automatic volume adjustment module is further configured to automatically adjust the volume setting to achieve the user-specific target signal-to-noise ratio given the ambient noise level.

6. The system of claim 4, wherein the automatic volume adjustment module is configured to automatically adjust the volume setting to achieve a default target signal-to-noise ratio given the ambient noise level;
wherein the user preference learning module is configured to derive a user-specific target signal-to-noise for each of a plurality of ambient noise level ranges by monitoring the one or more user-implemented adjustments made to the volume setting after the automatic adjustment thereof by the automatic volume adjustment module and to provide the user-specific target signal-to-noise ratios to the automatic volume adjustment module;
wherein the automatic volume adjustment module is further configured to select one of the user-specific target signal-to-noise ratios based on the ambient noise level and to automatically adjust the volume setting to achieve the selected user-specific target signal-to-noise ratio given the ambient noise level.

7. The system of claim 1, wherein:
the content delivery module comprises an image processor and a display, wherein the image processor is configured to render images to the display and wherein the brightness of the display is controlled in accordance with a brightness setting;
the automatic parameter adjustment module comprises an automatic brightness adjustment module that is configured to automatically adjust the value of the brightness setting based on at least an environmental lighting condition;
the user preference learning module is configured to derive the user preference information by monitoring one or more user-implemented adjustments made to the brightness setting after the automatic adjustment thereof by the automatic brightness adjustment module; and
wherein the automatic brightness adjustment module is further configured to automatically adjust the brightness setting based on at least the environmental lighting condition and the user preference information.

8. The system of claim 7, wherein the images comprise images in a series of images that comprise video content.

9. The system of claim 7, wherein the environmental lighting condition comprises an ambient light level.

10. The system of claim 9, further comprising:
one or more light sensors;
a light sensor data processor that is configured to determine the ambient light level by processing data produced by the one or more light sensors.

11. The system of claim 1, wherein the user preference learning module is configured to derive user preference information associated with a plurality of users by monitoring the one or more user-implemented adjustments made to the value of the content delivery parameter after the automatic adjustment thereof by the automatic parameter adjustment module and to provide the user preference information associated with each of the plurality of users to the automatic parameter adjustment module; and
wherein the automatic parameter adjustment module is further configured to automatically adjust the value of the content delivery parameter based on at least the environmental condition and the user preference information associated with an identified one of the plurality of users.

12. The system of claim 1, wherein the content delivery module is configured to deliver haptic content to the user in accordance with the value of the content delivery parameter.

13. A method, comprising:
(a) automatically adjusting a value of a parameter relating to delivery of media content based on at least an environmental condition;
(b) delivering media content in accordance with the value of the parameter obtained by the automatic adjustment of step (a);
(c) deriving user preference information by monitoring one or more user-implemented adjustments made to the value of the parameter after the automatic adjustment of step (a);
(d) automatically adjusting the value of the parameter based on at least the environmental condition and the user preference information; and
(e) delivering media content in accordance with the value of the parameter obtained by the automatic adjustment of step (d).

14. The method of claim 13, wherein:
step (a) comprises automatically adjusting a volume setting based on at least an environmental noise condition;
step (b) comprises outputting an audio signal at the volume setting obtained by the automatic adjustment of step (a);
step (c) comprises deriving the user preference information by monitoring one or more user-implemented adjustments made to the volume setting after the automatic adjustment of step (a);
step (d) comprises automatically adjusting the volume setting based on at least the environmental noise condition and the user preference information; and
step (e) comprises outputting the audio signal at the volume setting obtained by the automatic adjustment of step (d).

15. The method of claim 14, wherein step (a) comprises determining the environmental noise condition by processing data produced by one or more microphones.

16. The method of claim 14, wherein step (a) comprises automatically adjusting the volume setting based on at least an ambient noise level.

17. The method of claim 16, wherein step (a) comprises automatically adjusting the volume setting to achieve a default target signal-to-noise ratio given the ambient noise level;
step (c) comprises deriving a user-specific target signal-to-noise ratio by monitoring the one or more user-implemented adjustments made to the volume setting after the automatic adjustment of step (a); and
step (d) comprises automatically adjusting the volume setting to achieve the user-specific target signal-to-noise ratio given the ambient noise level.

18. The method of claim 16, wherein step (a) comprises automatically adjusting the volume setting to achieve a default target signal-to-noise ratio given the ambient noise level;
step (c) comprises deriving a user-specific target signal-to-noise ratio for each of a plurality of ambient noise level ranges by monitoring one or more user-implemented adjustments made to the volume setting after the automatic adjustment of step (a); and
step (d) comprises selecting one of the user-specific target signal-to-noise ratios based on the ambient noise level and automatically adjusting the volume setting to achieve the selected user-specific target signal-to-noise ratio given the ambient noise level.

19. The method of claim 13, wherein:
step (a) comprises automatically adjusting a brightness setting based on at least an environmental lighting condition;
step (b) comprises setting a brightness of a display in accordance with the brightness setting obtained by the automatic adjustment of step (a) and rendering one or more images to the display;
step (c) comprises deriving the user preference information by monitoring one or more user-implemented adjustments made to the brightness setting after the automatic adjustment of step (a);
step (d) comprises automatically adjusting the brightness setting based on at least the environmental lighting condition and the user preference information; and
step (e) comprises setting the brightness of the display in accordance with the brightness setting obtained in step (d) and rendering one or more images to the display.

20. The method of claim 19, wherein the one or more images rendered to the display comprise a series of images comprising video content.

21. The method of claim 19, wherein step (a) comprises automatically adjusting the brightness setting based on at least an ambient light level.

22. The method of claim 21, wherein step (a) further comprises determining the ambient light level by processing data generated by one or more light sensors.

23. The method of claim 13, wherein the media content comprises haptic content.

24. A system comprising:
a content delivery module configured to output media content to a user in accordance with a content delivery parameter; and
an automatic parameter adjustment module that is configured to automatically adjust a value of the content delivery parameter based on at least a sensed environmental condition and automatically-learned user preference data.

25. The system of claim 24, wherein the content delivery module is configured to output an audio signal in accordance with a volume setting; and
wherein the automatic parameter adjustment module comprises an automatic volume adjustment module that is configured to automatically adjust the volume setting based on at least a sensed environmental noise condition and the automatically-learned user preference data.

26. The system of claim 25, wherein the sensed environmental noise condition comprises an ambient noise level.

27. The system of claim 25, wherein the automatically-learned user preference data comprises a user-specific target signal-to-noise ratio.

28. The system of claim 25, wherein the automatically-learned user preference data comprises a plurality of user-specific target signal-to-noise ratios corresponding to a plurality of ranges of ambient noise levels.

29. The system of claim 24, wherein the content delivery module is configured to output images to a display having a brightness controlled in accordance with a brightness setting; and
wherein the automatic parameter adjustment module comprises an automatic brightness adjustment module that is configure to automatically adjust the brightness setting based on at least a sensed environmental lighting condition and the automatically-learned user preference data.

30. The system of claim 29, wherein the sensed environmental lighting condition comprises an ambient light level.
